(19) United States
(12) Patent Application Publication
(10) Pub. No.: US 2004/0082179 A1
(43) Pub. Date: Apr. 29, 2004

(54) Method for forming metal coating and method for manufacturing chip electronic components

(75) Inventors: Kenichi Saito, Fukui-ken (JP); Hisato Oshima, Takefu-shi (JP); Takaaki Oi, Takefu-shi (JP)

Correspondence Address: Keating & Bennett LLP, Suite 312, 10400 Eaton Place, Fairfax, VA, 22030, US

(73) Assignee: Murata Manufacturing Co., Ltd., Nagaokakyo-shi (JP)

(21) Appl. No.: 10/674,632

(22) Filed: Sep. 29, 2003

(30) Foreign Application Priority Data
Oct. 23, 2002 (JP) 2002-308775
Jul. 25, 2003 (JP) 2003-201697

(51) Int. Cl. H01L 21/311

(52) U.S. Cl. 438/696

(57) ABSTRACT

A metal coating-forming method and a method of manufacturing a chip electronic component is performed such that a wiring pattern or external electrodes can easily be formed by the use of a readily removable coating layer without deterioration in the safety of the work environment. The method includes the steps of forming a coating layer on a component element surface with an ink paint that is soluble in a rinsing solution principally including alcohol, removing the coating layer disposed on both ends where external electrodes are to be formed by a blasting process, forming an electroless metal coating over the component element, and rinsing the resulting component element to remove the coating layer disposed on a region where no external electrodes are formed and the electroless metal coating attached thereon.

### BACKGROUND OF THE INVENTION

1. Field of the Invention

The present invention relates to methods for forming metal coatings and methods for manufacturing chip electronic components. The present invention particularly relates to a method for forming a metal coating on a printed circuit board or ceramic substrate, or relates to a method for manufacturing chip electronic components wherein external electrodes disposed on corresponding ends of a component element, which includes an internal conductor disposed therein, are electrically connected to the internal conductor, such as bead inductors, capacitors, noise filters, varistors, or thermistors.

2. Description of the Related Art

One well-known example of chip electronic components is an inductor wherein a coil is contained in a material, which is a mixture of magnetic powder and a resin, to form an element by a molding process, and on both ends of the element external electrodes are disposed and are connected to the coil.

This type of inductor, however, has a problem in that, because conductive paste is applied to the element and then fired to form the external electrodes, the resin in the element is degenerated and decomposed due to heat applied during the firing and its properties are lowered.

In view of the above-described problems, the inventors have already proposed a manufacturing method disclosed in Japanese Unexamined Patent Application Publication No. 2001-135541 (hereinafter referred to as Patent Document 1). In this method, a region of a component element on which no external electrode is formed is coated with a resist agent, and an electroless Ni coating is formed over the entire surface of the component element, and the component element is immersed in an aqueous sodium hydroxide solution to remove the resist coating and the electroless Ni coating attached thereon, and an electrolytic Ni coating and an electrolytic Sn coating are then applied on remaining portions of the electroless Ni coating.

The use of a resist agent as in the manufacturing method disclosed in Patent Document 1, however, has a problem in that the resist coating cannot be readily peeled off (that is, dissolved) from the component element by immersing the component element in the aqueous sodium hydroxide solution because the resist coating has been thermally cured. Furthermore, there is still another problem in that handling of a deleterious substance, aqueous sodium hydroxide solution, can worsen the work environment.

### SUMMARY OF THE INVENTION

In order to overcome the problems described above, preferred embodiments of the present invention provide a metal coating-forming method and chip electronic component-manufacturing method wherein wiring patterns and external electrodes can be readily formed by use of a easily-removable coating layer without deterioration in the work environment.

According to a first preferred embodiment of the present invention, a method for forming a metal coating includes forming a coating layer with an ink paint that is soluble in a rinsing solution principally including alcohol over the surface of a component element having a base layer for a wiring pattern thereon, removing the coating layer from the whole area or a portion of the base layer, forming an electroless metal coating over the surface of the component element, and rinsing the component element having the electroless metal coating thereon with the rinsing solution to remove the coating layer and the electroless metal coating attached onto the coating layer.

According to a second preferred embodiment of the present invention, a method for forming a metal coatings includes forming a coating layer over the surface of a component element with an ink paint that is soluble in a rinsing solution principally including alcohol, removing the coating layer disposed on a region of the component element on which a metal coating are to be formed, forming an electroless metal coating on the surface of the component element, and rinsing the component element having the electroless metal coating thereon with the rinsing solution to remove the coating layer and the electroless metal coating attached onto the coating layer.

In the first and second preferred embodiments of the present invention, an ink paint that is soluble in the rinsing solution principally including alcohol is preferably used for the coating layer. This type of ink paint has high acid resistance and alkali resistance but has low solvent resistance, that is, low water resistance or solution resistance, and therefore can be readily removed from the surface of the component element. Furthermore, this type of ink paint is safe for humans, and the safety of the work environment can be maintained.

In the first and second preferred embodiments, chip electronic components including an internal conductor therein, or a single-layer or a multi-layer substrate including a resin or ceramic can be used as the component element.

According to a third preferred embodiment of the present invention, a method for manufacturing chip electronic components, among methods for manufacturing chip electronic components wherein external electrodes disposed on both ends of a component element, which has an internal conductor disposed therein, are electrically connected to the internal conductor, includes a step of forming a coating layer over the surface of the component element with an ink paint that is soluble in a rinsing solution principally including alcohol, removing the coating layer disposed on a region of the component element on which external electrodes are to be formed, forming an electroless metal coating over the entire surface of the component element, and rinsing the component element having the electroless metal coating thereon with the rinsing solution to remove the coating layer on which no external electrode is to be formed and the electroless metal coating attached onto the coating layer.

Also in the third preferred embodiment of the present invention, an ink paint that is soluble in the rinsing solution principally including alcohol is used for the coating layer, and the same advantages as those of the methods of the first and second preferred embodiments can be obtained.

In the third preferred embodiment, the component element is preferably polished in a rotating barrel during or after the rinsing step. The coating layer and the electroless metal coating applied onto the coating layer can be speedily and securely removed by polishing process.

According to the fourth preferred embodiment of the present invention, among methods for manufacturing chip electronic components wherein external electrodes disposed on both ends of a component element, which has an internal conductor disposed therein, are electrically connected to the internal conductor, includes forming a coating layer over the surface of the component element with an ink paint that is soluble in a rinsing solution principally including alcohol, removing the coating layer disposed on a region of the component element on which external electrodes are to be formed, rinsing the component element with the rinsing solution to remove a portion of the coating layer on which no external electrode is to be formed, and forming an electroless metal coating on a region of the component element on which external electrodes are to be formed.

In the fourth preferred embodiment, the step of removing the coating layer with an ink paint before application of the electroless metal coating preferably includes the following two steps: a primary-removal step of removing the coating layer disposed on a region of the component element on which external electrodes are to be formed, and a secondary-removal step of removing the coating layer disposed on a region on which no external electrode is to be formed. A portion of the surface of the component element, from which the coating layer disposed on a region on which no external electrode is cleared in the secondary-removal step, is smooth, so electroless metal coating cannot grow thereon, and is formed only on a region of the surface of the component element from which the coating layer is removed in the primary-removal step.

In the fourth preferred embodiment of the present invention, as well as the first, second, and third preferred embodiments, the ink paint that is soluble in the rinsing solution principally including alcohol is preferably used for forming the coating layer. Therefore, the coating layer can be readily removed from the surface of the component element without deterioration in the safety of the work environment, and the polishing process with a rotating barrel is unnecessary, which leads to cost reduction.

In the third and fourth preferred embodiments, for the step of removing the coating layer disposed on the region of the component element surface on which external electrodes are to be formed, either a dry blasting process by spraying particles or a wet blasting process by spraying a mixture of particles and a solution can be used. By surface roughening of the region on which external electrodes are to be formed, the electroless metal coatings can be efficiently formed thereon.

In the first, second, third, and fourth preferred embodiments, the ink paint preferably includes a maleic acid resin. And when the rinsing step includes an ultrasonic-rinsing process with isopropyl alcohol as the rinsing solution, the coating layer can be efficiently removed.

Furthermore, before the electroless metal coating-forming step, the component element may be immersed in a Pd solution, which functions as a catalyst in an electroless plating process.

The third and fourth preferred embodiments may further include a step of forming external electrodes by forming an electrolytic metal layer through electrolytic plating onto the electroless metal coating as a base electrode. External electrodes can be efficiently formed by electrolytic plating.

Furthermore, the component element may be formed by embedding a coil into a magnetic resin containing a resin and magnetic powder, and connecting the external electrodes electrically to the end of the coil exposed at the both ends of the component element. Thus, with the component element, a satisfactory chip bead inductor can be obtained.

Other features, elements, steps, characteristics and advantages of the present invention will become more apparent from the following detailed description of preferred embodiments thereof with reference to the attached drawings.

### BRIEF DESCRIPTION OF THE DRAWINGS

FIG. 1 is an illustration showing a component element obtained in an element-preparing step of a manufacturing method according to a preferred embodiment of the present invention;

FIG. 2 is an illustration showing the component element processed in an ink paint-applying step of the manufacturing method according to a preferred embodiment of the present invention;

FIG. 3 is an illustration showing a blasting step of the manufacturing method according to a preferred embodiment of the present invention;

FIG. 4 is an illustration showing the component element processed in the blasting step of the manufacturing method according to a preferred embodiment of the present invention;

FIG. 5 is an illustration showing the component element processed in an electroless plating step of the manufacturing method according to a preferred embodiment of the present invention;

FIG. 6 is an illustration showing the component element processed in a rinsing/polishing step of the manufacturing method according to a preferred embodiment of the present invention;

FIG. 7 is an illustration showing the component element processed in an external electrode-forming step of the manufacturing method according to a preferred embodiment of the present invention; and

FIG. 8 is a perspective view showing a printed circuit board obtained by a metal coating-forming method according to preferred embodiments of the present invention.

### DETAILED DESCRIPTION OF PREFERRED EMBODIMENTS

Preferred embodiments of the present invention will now be described with reference to the attached drawings.

First Preferred Embodiment

In the first preferred embodiment of the present invention, chip bead inductors are manufactured in the steps described below.

Element-Preparing Step:

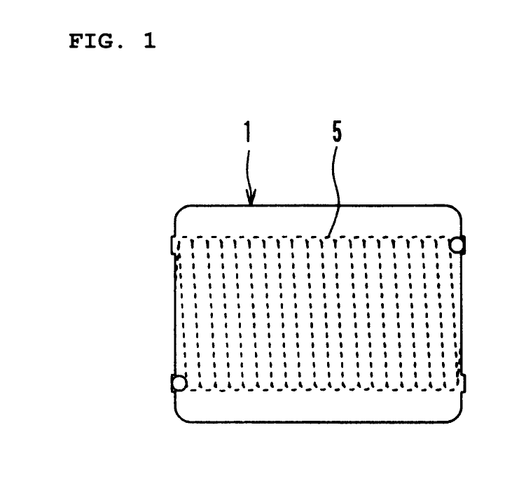

A component element 1 is prepared in this step, an example of which is shown in FIG. 1. Ferrite powder and polyphenylene sulfide resin are mixed together at the ratio of about 85 to about 15 on a weight basis to prepare a resin mixture. On the other hand, a copper wire with a polyamidoimide insulating film having a thickness of about 0.2 mm to about 0.3 mm is densely wound to prepare a fusion coil 5 of about 1.8 mm diameter. The coil 5 has a free length of about 4.5 mm.

The coil 5 is inserted into a movable protective pin, with the pin projected within a mold, and the mixed resin is injected onto the outer circumference, from the side, of the coil 5. Then, the protective pin is taken out and the mixed resin is injected onto the inner circumference of coil 5. Thereby, the component element 1 with the built-in coil 5 is obtained. Both ends of the coil 5 are partially exposed at both ends of the component element 1. The component element 1 is taken out of the mold, cut at gate sections thereof, rinsed and dried for the next step.

Ink Paint-Applying Step:

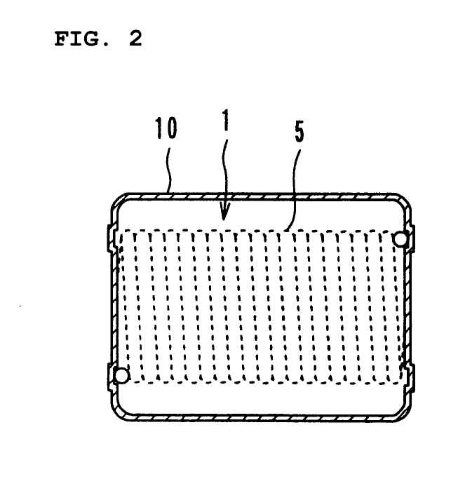

As shown in FIG. 2, the component element 1 is coated with an ink paint by a resin-impregnation method to form coating layers 10 thereon. The ink paint is soluble in a rinsing solution which principally includes alcohol, and an oil-base ink paint used for writing implements made of paper, glass, vinyl, wood, metal, ceramic, or plastic. Generally, the ink paint excels in acid resistance and alkali resistance, though it has low solvent (water/solution) resistance. The ink paint used herein preferably includes a rosin-modified maleic resin (a maleic resin and a derivative thereof) as a dispersant, organic azo pigment, and an organic solvent including isobutanol, ethylcellosolve, and xylene. In addition, a maleic resin can be used in either simple-substance or composite.

The ink paint preferably has a viscosity of about 1,500 MPa to about 3,000 MPa at 25° C. before dilution, and before use it should be mixed with the rinsing solution described below at the ratio of about 1:1 to about 1:2.

Then coating layer 10 is air-dried by vibrating the component elements 1 in such a way that the component elements 1 are not joined to each other.

Blasting Step:

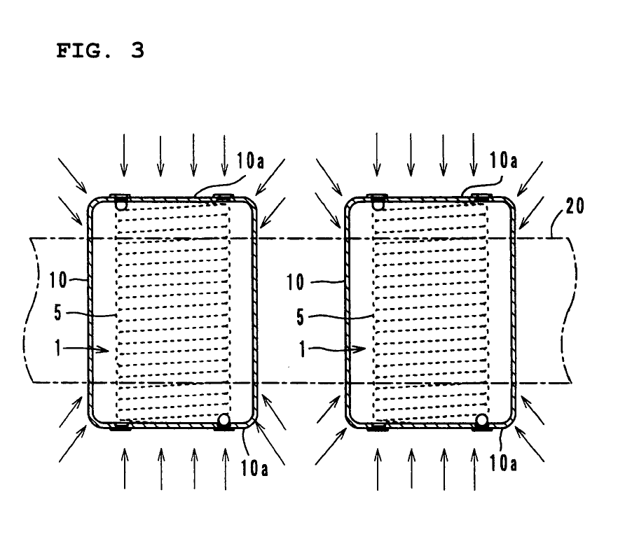

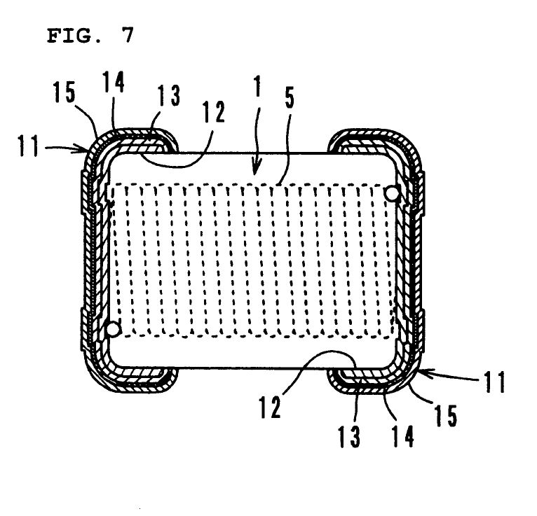

As shown in FIG. 3, a plurality of the component elements 1 with coating layers 10 are held by masking with a holder 20. The holder 20 includes a fluorine resin or a silicon resin, and has holding spaces that are substantially rectangular-shaped in cross section, which are used to mask the center area of each component element. The component elements 1 are each inserted and held in a corresponding holding space, and thereby a region of each component element 1 on which external electrodes 11, shown in FIG. 7, are not to be formed, is masked.

The component elements 1 held in the holder 20 go through a wet blasting process where a mixture of an alumina abrasive and a solution is ejected in the direction indicated by the arrow shown in FIG. 3. A dry blasting process where particles are ejected can be used instead.

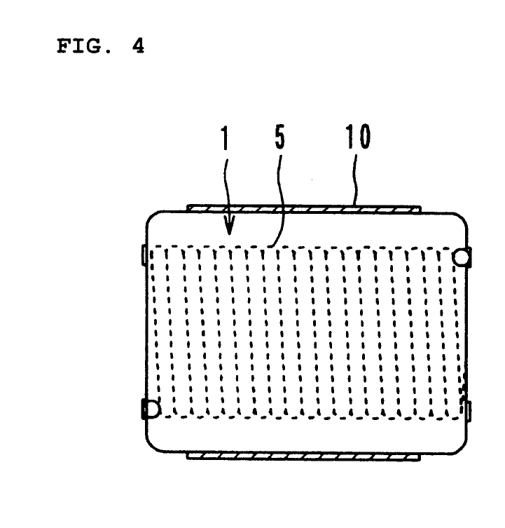

By such a blasting process, the coating layer 10a disposed on an unmasked region on which the external electrodes 11 are to be formed is removed, and a region from which the coating layer 10a is removed is surface roughened, and then the insulating film disposed on both ends of the coil 5 is removed. FIG. 4 shows the component element 1, taken out of the holder 2 after a blasting process.

Pretreatment Step for Electroless Plating;

In order to remove an oxide layer disposed on both ends of the coil 5, the component element 1 after the blasting process has been performed is etched with a ferric oxide solution and then cleaned. The resulting component element 1 is maintained wet on the surface.

Next, the component element 1 is immersed in a Pd solution, which functions as a catalyst in the next step, that is, an electroless plating process. In addition, the wet treatment is necessary for Pd to stick readily on the component element 1.

Electroless Plating Step:

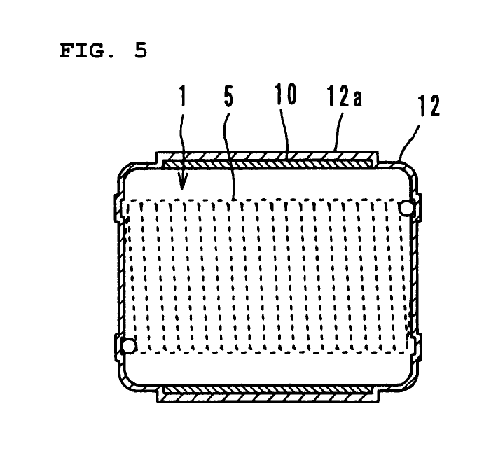

As shown in FIG. 5, the resulting component element 1 goes through the electroless plating process. In this step, the electroless Ni coating 12 is applied to be about 1 μm thick. The electroless Ni coating 12 is applied onto not only a region of the component element 1 on which external electrodes are to be formed, but also the surface of the coating layer 10.

Rinsing/Polishing Step;

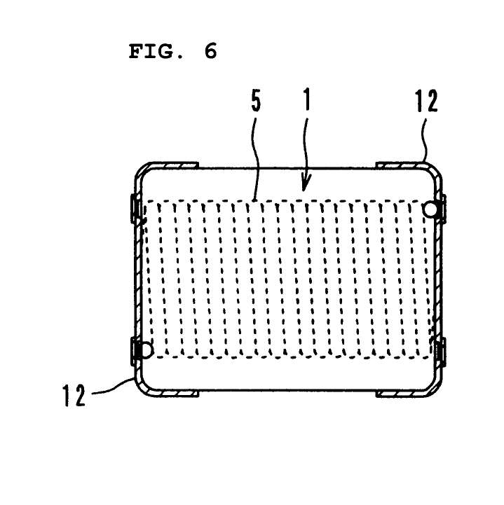

The component element 1 with the electroless Ni coating 12a thereon is rinsed. First, the component element 1 is ultrasonically rinsed with isopropyl alcohol as a rinsing solution, and during this rinsing process, the component element 1 is also polished with a rotating barrel. Thereby, the coating layer 10 and the electroless Ni coating 12a attached thereon are removed as shown in FIG. 5, and the remaining portion of the electroless Ni coating, 12, is left on the component element 1, as shown in FIG. 6.

External Electrode-forming Step:

On the electroless Ni coating 12, which is used as a base electrode, a Cu layer 13 having a thickness of about 10 μm to about 20 μm is formed by electrolytic plating. Next, a Ni layer 14 having a thickness of about 1 μm is formed on the Cu layer 13 by electrolytic plating, and a Sn layer 15 with about 5 μm thickness is formed on the Ni layer 14 by electrolytic plating, to obtain external electrodes 11, as shown in FIG. 7.

According to the first preferred embodiment, a coating layer 10 disposed on a region of the component element 1 on which external electrodes 11 are not to be formed is dissolved in the rinsing process because it contains the ink paint, and therefore, the electroless Ni coating 12a disposed thereon cannot securely adhere to the component element 1. Then, the electroless Ni coating 12a is removed by the ultrasonic rinsing treatment and the polishing treatment with a rotating barrel. The remaining portion of the electroless Ni coating, 12, is consequently left only on a region which is to be a base electrode for the external electrode 11. Thus, the following step disclosed in Patent Document 1 is not needed: a step of removing an unnecessary portion of the electroless metal coating by etching with acid.

Since the ink paint can be easily and reliably removed and dissolved by the isopropyl alcohol, the agents with low risk are used in the steps.

Second Preferred Embodiment

A manufacturing method according to the second preferred embodiment of the present invention includes substantially the same steps as those of the first preferred embodiment except that after the blasting step, the remaining coating layer 10 is removed as well and the electroless plating treatment is then performed, although the rinsing/polishing step is omitted. The second preferred embodiment is described below in detail.

Element-Preparing Step:

An element-preparing step is substantially the same as that of the first preferred embodiment illustrated in FIG. 1.

Ink Paint-Applying Step:

An ink paint-applying step is substantially the same as that of the first preferred embodiment illustrated in FIG. 2.

Blasting Step (Primary-removal step of coating layer):

A blasting step is substantially the same as that of the first preferred embodiment illustrated in FIG. 3.

Rinsing Step (Secondary-removal step of coating layer):

In this step, a rinsing process is performed over the component element 1 with the coating layer 10 left on a region on which the external electrodes 11 are not to be formed. That is, the component element 1 is ultrasonically rinsed with isopropyl alcohol as a rinsing solution. On the other hand, the polishing step with a rotating barrel is unnecessary in this second preferred embodiment. Thereby, the remaining coating layer 10 is removed.

Electroless Plating Step:

The resulting component element 1 goes through an electroless plating process, as in the first preferred embodiment, to form electroless Ni coating 12a with a thickness of about 1 μm. In this electroless plating process, no electroless Ni coating is formed on a smooth region of the surface of the component element 1 from which the coating layer 10, disposed on a region where external electrodes are not to be formed, is removed. The electroless Ni coating 12 grows only on a blasted region on which external electrodes are to be formed.

External Electrode-forming Step:

An external electrode-forming step is the same as that of the first preferred embodiment illustrated in FIG. 7.

According to the present preferred embodiment, the same advantages as those of the first preferred embodiment can be obtained. In addition, external electrodes 11 do not require polishing with a rotating barrel, which leads to cost reduction.

Third Preferred Embodiment

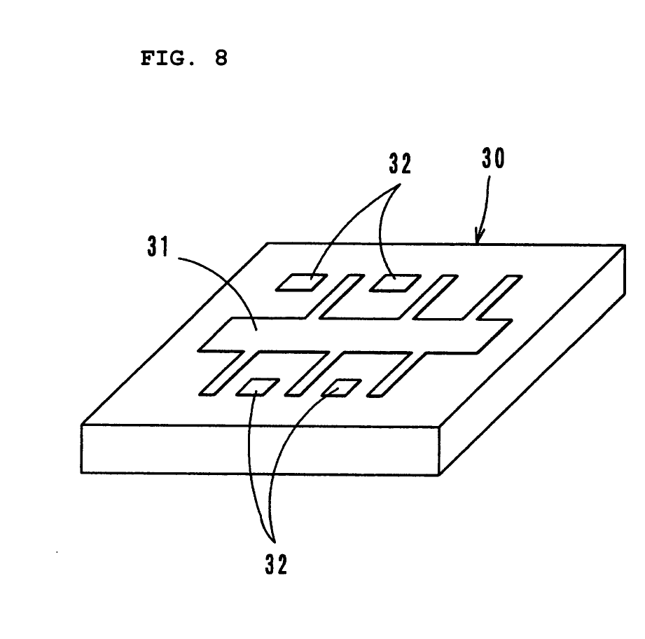

In a metal-coating-forming method according to the third preferred embodiment of the present invention, an electroless metal coating is formed on a printed circuit board 30 made of resin shown in FIG. 8. This preferred embodiment is schematically described below, and its details are substantially the same as those of the first and second preferred embodiments of the present invention.

A coating layer is formed, with the ink paint that is soluble in a rinsing solution principally including alcohol, on the surface of the printed circuit board 30 with base layers 31 and 32 for forming a wiring pattern. Then, the coating layer disposed on the base layers 31 and 32 are entirely or partially removed. That is, coating layer is removed only from a region on which the electroless metal coating is desirably attached. In this step, the coating layer is preferably removed by a dry blasting process with the use of particles or a wet blasting process with the use of a mixture of particles and a solvent.

Next, an electroless metal coating is formed over the entire surface of the printed circuit board 30. The resulting printed circuit board 30 with the electroless metal coating thereon is then rinsed with the rinsing solution, to remove the coating layer and the electroless metal coating disposed on the coating layer. As a result, the electroless metal coating remains on the base layers 31 and 32.

Fourth Preferred Embodiment

In a metal coating-forming method according to the fourth preferred embodiment of the present invention, as well as the third preferred embodiment, an electroless metal coating is formed on a printed circuit board 30 made of resin as shown in FIG. 8. This preferred embodiment is schematically described below, and its details are substantially the same as those of the first and second preferred embodiments of the present invention.

A coating layer is formed, with an ink paint that is soluble in a rinsing solution principally including alcohol, on the surface of the printed circuit board 30 with no elements thereon. Then, the coating layer disposed on a region on which the electroless metal coating portions 31 and 32 are to be formed, is removed. In this step, the coating layer is preferably removed by a dry blasting process with the use of particles or a wet blasting process with the use of a mixture of particles and a solvent.

Next, an electroless metal coating is formed on the surface of the printed circuit board 30. The resulting printed circuit board 30 with the electroless metal coating thereon is then rinsed with the rinsing solution, to remove the coating layer and the electroless metal coating disposed on the coating layer. As a result, the electroless metal coating portions 31 and 32 remain on printed circuit 30.

Other Preferred Embodiments

A metal coating-forming method and a chip electronic component-manufacturing method of the present invention are not limited to the above-described preferred embodiments, and various modifications are possible within the scope of the present invention.

In particular, the shape in detail of the component element and coil is arbitrary. Of course, materials for the component element and the coil used in the first and second preferred embodiments, the ink paint and solutions used in each process, and abrasives used in a blasting step are all cited merely as examples and may be changed as desired.

A manufacturing method of various preferred embodiments of the present invention can be applied to various electronic components, other than chip bead inductors, such as capacitors, noise filters, varistors, thermistors and so on.

In a metal coating-forming method according to the present invention, as a printed circuit board 30 shown in the third and fourth preferred embodiments, either a single-layer substrate or a multi-layer substrate can be used, and a ceramic substrate is preferably used whether it is a single-layer substrate or a multi-layer substrate. In the case of a multi-layer substrate, electrodes and/or a conductor may be included therein.

As is clear from the above description, according to a metal coating-forming method and a chip electronic component-manufacturing method of various preferred embodiments of the present invention, an ink paint that is soluble in a rinsing solution principally including alcohol is preferably used for a coating layer to form an electroless metal layer. Thus, such a coating layer can be readily removed with a safe solvent other than acid.

It should be understood that the foregoing description is only illustrative of the present invention. Various alternatives and modifications can be devised by those skilled in the art without departing from the present invention. Accordingly, the present invention is intended to embrace all such alternatives, modifications and variances which fall within the scope of the appended claims.

What is claimed is:

1. A method for forming a metal coating, comprising the steps of:
forming a coating layer, with an ink paint that is soluble in a rinsing solution principally including alcohol, over a surface of a component element on which a base layer for a wiring pattern is provided;
removing entirely or partially the coating layer disposed on the base layer;
forming an electroless metal coating over the surface of the component element; and
rinsing the component element with the electroless metal coating thereon with the rinsing solution to remove the coating layer and the electroless metal coating attached onto the coating layer.

2. The method according to claim 1, wherein the removing step uses a dry blasting process with particles or a wet blasting process with a mixture of a solution and particles.

3. The method according to claim 1, wherein the component element is a chip electronic component including an internal conductor disposed therein.

4. The method according to claim 1, wherein the component element includes one of a single layer substrate and a multi-layer substrate, and the component element includes one of a resin and a ceramic.

5. The method according to claim 1, wherein the ink paint includes a maleic acid resin.

6. The method according to claim 1, wherein the rinsing step includes performing an ultrasonic-rinsing process with isopropyl alcohol being used as the rinsing solution.

7. The method according to claim 1, further comprising a step of immersing the component element in a Pd solution before the electroless metal coating-forming step.

8. A method for forming a metal coating, comprising the steps of:
forming a coating layer over a surface of a component element with an ink paint that is soluble in a rinsing solution principally including alcohol;
removing the coating layer disposed on a region of the component element on which a metal coating is to be formed;
forming an electroless metal coating on the component element; and
rinsing the component element with the electroless metal coating thereon with the rinsing solution to remove the coating layer and the electroless metal coating attached on the coating layer.

9. The method according to claim 8, wherein the removing step uses a dry blasting process with particles or a wet blasting process with a mixture of a solution and particles.

10. The method according to claim 8, wherein the component element is a chip electronic component including an internal conductor disposed therein.

11. The method according to claim 8, wherein the component element includes one of a single layer substrate and a multi-layer substrate, and the component element includes one of a resin and a ceramic.

12. The method according to claim 8, wherein the ink paint includes a maleic acid resin.

13. The method according to claim 8, wherein the rinsing step includes performing an ultrasonic-rinsing process with isopropyl alcohol being used as the rinsing solution.

14. The method according to claim 8, further comprising a step of immersing the component element in a Pd solution before the electroless metal coating-forming step.

15. A method for manufacturing chip electronic component including a component element with an internal conductor disposed therein, and external electrodes each disposed on corresponding ends of the component element and electrically connected to the internal conductor, the method comprising the steps of:
forming a coating layer over a surface of the component element with an ink paint that is soluble in a rinsing solution principally including alcohol;
removing the coating layer disposed on a region of the component element on which the external electrodes are to be formed;
forming an electroless metal coating over the entire surface of the component element; and
rinsing the component element with the electroless metal coating thereon with the rinsing solution to remove the coating layer on a region on which no external electrode is to be formed and the electroless metal coating attached onto the coating layer portion.

16. The method according to claim 15, further comprising a step of polishing the component element with a rotating barrel to remove the coating layer and the electroless metal coating disposed on the coating layer portion, after the rinsing step.

17. The method according to claim 15, wherein the rinsing step includes a step of polishing the component element with a rotating barrel to remove the coating layer and the electroless metal coating disposed on the coating layer portion.

18. The method according to claim 15, wherein the removing step uses a dry blasting process with particles or a wet blasting process with a mixture of a solution and particles.

19. The method according to claim 15, wherein the ink paint includes a maleic acid resin.

20. The method according to claim 15, wherein the rinsing step includes the step of performing an ultrasonic-rinsing process with isopropyl alcohol being used as the rinsing solution.

21. The method according to claim 15, further comprising a step of forming the external electrodes by applying a metal coating in an electrolytic plating process on the electroless metal coating which defines a base electrode.

22. The method according to claim 15, further comprising a step of immersing the component element in a Pd solution before the electroless metal coating-forming step.

23. The method according to claim 15, wherein the component element includes a coil embedded into a magnetic resin including a resin and magnetic powder dispersed therein, and the external electrodes are each electrically connected to the corresponding ends of the coil exposed at both ends of the component element.

24. A method for manufacturing chip electronic component including a component element with an internal conductor disposed therein, and external electrodes each disposed on corresponding ends of the component element and electrically connected to the internal conductor, the method comprising the steps of:
forming a coating layer over a surface of the component element with an ink paint that is soluble in a rinsing solution principally including alcohol;
removing the coating layer disposed on a region of the component element on which the external electrodes are to be formed;
rinsing the component element with the rinsing solution to remove the coating layer on a region on which no external electrode is to be formed;
and forming electroless metal coating on a region of the component element on which the external electrodes are to be formed.

25. The method according to claim 24, wherein the removing step uses a dry blasting process with particles or a wet blasting process with a mixture of a solution and particles.

26. The method according to claim 24, wherein the ink paint includes a maleic acid resin.

27. The method according to claim 24, wherein the rinsing step includes performing an ultrasonic-rinsing process with isopropyl alcohol being used as the rinsing solution.

28. The method according to claim 24, further comprising a step of forming the external electrodes by applying metal coating in an electrolytic plating process on the electroless metal coating which defines a base electrode.

29. The method according to claim 24, further comprising a step of immersing the component element in a Pd solution before the electroless metal coating-forming step.

30. The method according to claim 24, wherein the component element includes a coil embedded into a magnetic resin including a resin and magnetic powder dispersed therein, and the external electrodes are each electrically connected to the corresponding ends of the coil exposed at both ends of the component element.
